(19) United States
(12) Patent Application Publication
(10) Pub. No.: US 2025/0142933 A1
(43) Pub. Date: May 1, 2025

(54) RADIO FREQUENCY DEVICE

(71) Applicant: UNITED MICROELECTRONICS CORP., Hsin-Chu City (TW)

(72) Inventors: Su Xing, Singapore (SG); Jinyu Liao, Singapore (SG)

(73) Assignee: UNITED MICROELECTRONICS CORP., Hsin-Chu City (TW)

(21) Appl. No.: 18/505,135

(22) Filed: Nov. 9, 2023

(30) Foreign Application Priority Data
Oct. 26, 2023 (TW) 112140952

(51) Int. Cl. H01L 29/423; H01L 23/552

(52) U.S. Cl. CPC H10D 64/519; H01L 23/552

(57) ABSTRACT

A radio-frequency (RF) device includes a gate structure extending along a first direction on a substrate, a source/drain region adjacent to two sides of the gate structure, a shallow trench isolation (STI) around the source/drain region, and a shielding structure extending from the gate structure and overlapping an edge of the STI. The gate structure includes a T-shape, in which the T-shape further includes a vertical portion extending along the first direction and a horizontal portion extending along a second direction. The RF device further includes a body region adjacent to the horizontal portion, in which the body region and the source/drain region have different conductive type.

### BACKGROUND OF THE INVENTION

### 1. Field of the Invention

The invention relates to a semiconductor device, and more particularly, to a radio frequency (RF) device.

### 2. Description of the Prior Art

As technology evolves, wireless communication is an important part of human life. Various electronic devices, such as smart phones, smart wearable devices, tablets, etc., utilize wireless radio frequency (RF) systems to transmit and receive wireless signals. A low noise amplifier (LNA) and a power amplifier (PA) are necessary amplifying circuits in the wireless RF system. In order to achieve better performance (e.g., linearity), the amplifying circuit requires an appropriate bias point. A common way is to electrically connect a biasing module to the amplifying circuit, so as to utilize the biasing module for providing a bias point for the amplifying circuit.

Nevertheless in conventional fabrication of RF devices, the relationship between gain and frequency measured after the fabrication process is often affected by the fabrication parameters to produce abnormal values that further induce noise in the substrate. Hence, how to improve current RF device structures for resolving this issue has become an important task in this field.

### SUMMARY OF THE INVENTION

According to an embodiment of the present invention, a radio-frequency (RF) device includes a gate structure extending along a first direction on a substrate, a source/drain region adjacent to two sides of the gate structure, a shallow trench isolation (STI) around the source/drain region, and a shielding structure extending from the gate structure and overlapping an edge of the STI. The gate structure includes a T-shape, in which the T-shape further includes a vertical portion extending along the first direction and a horizontal portion extending along a second direction. The RF device further includes a body region adjacent to the horizontal portion, in which the body region and the source/drain region have different conductive type.

According to another aspect of the present invention, a radio-frequency (RF) device includes a gate structure extending along a first direction on a substrate, a source/drain region adjacent to two sides of the gate structure, a shallow trench isolation (STI) around the source/drain region, and a doped region extending across the gate structure and overlapping an edge of the STI.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-4 illustrate a method for fabricating a RF device according to an embodiment of the present invention.

FIG. 5 illustrates a top view of a RF device according to an embodiment of the present invention.

FIG. 6 illustrates a top view of a RF device according to an embodiment of the present invention.

FIG. 7 illustrates a top view of a RF device according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

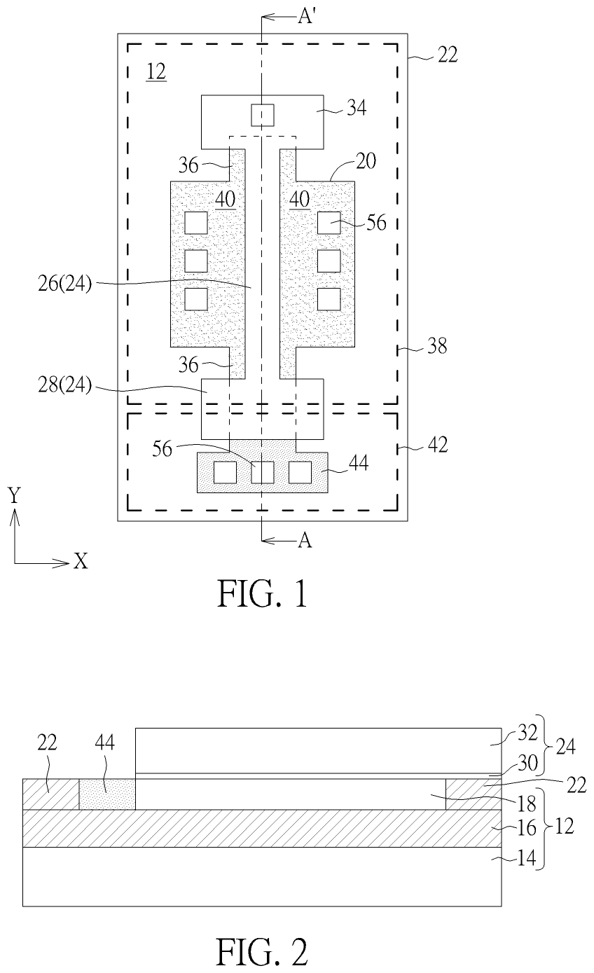

Referring to FIGS. 1-4, FIGS. 1-4 illustrate a method for fabricating a RF device according to an embodiment of the present invention, in which FIG. 1 is a top view for fabricating the RF device according to an embodiment of the present invention and FIGS. 2-4 are cross-section views for fabricating the semiconductor device taken along the sectional line AA′ of FIG. 1. A shown in FIGS. 1 and 2, a substrate 12 made of silicon material such as a silicon-on-insulator (SOI) substrate is provided, in which the substrate 12 includes a first semiconductor layer 14, an insulating layer 16 disposed on the first semiconductor layer 14, and a second semiconductor layer 18 disposed on the insulating layer 16. In this embodiment, the first semiconductor layer 14 and the second semiconductor layer 18 could be made of same material or different material and could both be made of material including but not limited to for example silicon, germanium, or silicon germanium (SiGe). The insulating layer 16 disposed between the first semiconductor layer 14 and second semiconductor layer 18 preferably includes SiO₂, but not limited thereto.

It should be noted that even though the substrate 12 in this embodiment pertains to be a SOI substrate, according to other embodiment of the present invention, the substrate 12 could also be a semiconductor substrate made of a silicon substrate, an epitaxial silicon substrate, or a silicon carbide (SiC) substrate, which are all within the scope of the present invention. Next, an active are 20 is defined on the substrate 12, and then part of the second semiconductor layer 18 outside the active area 20 is removed to form a shallow trench isolation (STI) 22 around the active area 20 or the remaining second semiconductor layer 18, in which an active device or TF device is to be fabricated on the second semiconductor layer 18 surrounded by the STI 22 in the later process.

Next, a gate structure 24 is formed on the substrate 12. From a top view perspective, the gate structure 24 is extending along a first direction such as Y-direction on the substrate 12, in which the gate structure 24 overall includes a T-shape, the T-shape further includes a vertical portion 26 and a horizontal portion 28, the vertical portion 26 is extending along the Y-direction on the active area 20, and the horizontal portion 28 is extending along the X-direction on the substrate 12 outside the active area 20.

It should be noted that the RF device of this embodiment also includes a shielding structure 34 extending from part of the gate structure 24 on the active area 20, in which the shielding structure 34 and the gate structure 24 are formed monolithically. In other words, if the gate structure 24 at this stage is made of polysilicon, the shielding structure 34 would also be made of polysilicon. If the gate structure 24 were transformed into a metal gate through a replacement metal gate (RMG) process in the later process, the shielding structure 34 would also be made of a metal gate.

Specifically, the shielding structure 34 and the horizontal portion 28 from the gate structure 24 are both extending along the X-direction and the width of the shielding structure 34 is preferably equal to the width of the horizontal portion 28. In this embodiment, the left and right sidewalls of the shielding structure 34 are aligned with left and right sidewalls of the horizontal portion 28. Nevertheless, according to other embodiment of the present invention, the shielding structure 34 and the gate structure 24 could have same width while the left and right sidewalls of the shielding structure 34 are not aligned with left and right sidewalls of the horizontal portion 28 along the Y-direction, which is also within the scope of the present invention.

From a cross-section perspective shown in FIG. 2, the formation of the gate structure 24 could be accomplished by a gate first process, a high-k first approach from gate last process, or a high-k last approach from gate last process. Since this embodiment pertains to a high-k last approach, a gate dielectric layer 30 or interfacial layer made of silicon oxide, a gate material layer 32 preferably made of polysilicon, and a selective hard mask (not shown) could be formed sequentially on the substrate 12, and a pattern transfer process is then conducted by using a patterned resist (not shown) as mask to remove part of the gate material layer 32 and part of the gate dielectric layer 30 through single or multiple etching processes. After stripping the patterned resist, a gate structure 24 composed of a patterned gate dielectric layer 30 and patterned gate material layer 32 is formed on the substrate 12.

Next, at least a spacer (not shown) is formed on sidewalls of the gate structure 24. In this embodiment, the spacer could be a single spacer or a composite spacer as the spacer could further include an offset spacer (not shown) and a main spacer (not shown). The offset spacer and the main spacer are preferably made of different materials while the offset spacer and main spacer could all be selected from the group consisting of SiO₂, SIN, SiON, and SiCN, but not limited thereto.

Next, a patterned mask (not shown) such as a patterned resist is formed to cover the region 42 including device such as part of the horizontal portion 28 and part of the STI 22 adjacent to the horizontal portion 28, and then an ion implantation process is conducted to form a doped region in the region 38 or the substrate 12 adjacent to two sides of the vertical portion 26 of the gate structure 24 serving as a source/drain region 40. The patterned mask is then removed thereafter. In this embodiment, the ion implantation process conducted at this stage preferably implants n-type dopants into the substrate 12 such that the source/drain region 40 formed is preferably a n+ region.

It should be noted that the during the ion implantation process for implanting n-type dopants into the substrate 12, it would be desirable to adjust the angle of the implantation process by implanting dopants at a tilted angle into corners between the vertical portion 26 and the horizontal portion 28, corners between the vertical portion 26 and the shielding structure 34, and even the substrate 12 directly under part of the horizontal portion 28 and the shielding structure 34 to form doped regions. In other words, as n-type dopants are implanted into the substrate 12 adjacent to two sides of the vertical portion 26 for forming the source/drain region 40, neck regions or neck doped regions 36 are formed at the same time in the corners between the horizontal portion 28 and the source/drain region 40 and between the shielding structure 34 and the source/drain region 40. Viewing form another perspective, the shielding structure 34 is disposed directly on the neck doped region 36 and adjacent STI 22.

Next, another patterned mask (not shown) such as a patterned resist is formed to cover part of the devices on the region 38 including the vertical portion 26 and part of the horizontal portion 28 of the gate structure 24, the source/drain region 40, and the shielding structure 34, and then an ion implantation process is conducted to form another doped region serving as a body region 44 in the region 42 or the substrate 12 below the horizontal portion 28. In this embodiment, the ion implantation process conducted at this stage preferably implants p-type dopants into the substrate 12 so that the body region 44 is preferably a p+ region.

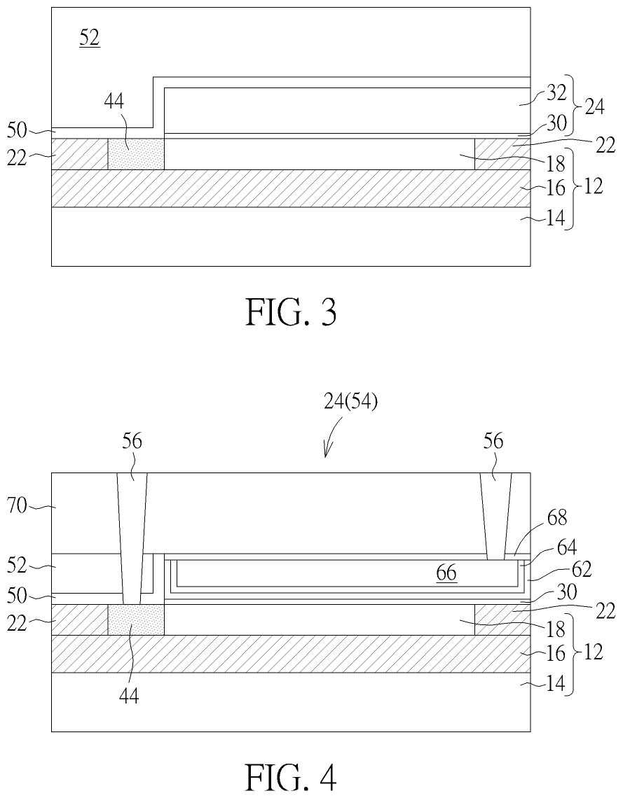

Referring to FIGS. 3-4, FIGS. 3-4 illustrate cross-section views for fabricating the RF device following FIG. 2 according to an embodiment of the present invention. As shown in FIG. 3, a selective salicide process could be conducted to form a silicide (not shown) on the surface of the source/drain region 40 and the body region 44, a contact etch stop layer (CESL) 50 made of silicon nitride could be formed on the substrate 12 to cover the gate structure 24, and then an inter-layer dielectric (ILD) layer 52 is formed on the CESL 50.

Next, as shown in FIG. 4, a planarizing process such as a chemical mechanical polishing (CMP) process is conducted to remove part of the ILD layer 52 and part of the CESL 50 so that the top surfaces of the CESL 50 and ILD layer 52 are coplanar.

Next, a replacement metal gate (RMG) process is conducted to transform the gate structure 24 into metal gate 54. For instance, the RMG process could be accomplished by first performing a selective dry etching or wet etching process using etchants including but not limited to for example ammonium hydroxide (NH₄OH) or tetramethylammonium hydroxide (TMAH) to remove the gate material layer 32 from gate structure 24 for forming a recess (not shown) in the ILD layer 52. Next, a high-k dielectric layer 62, a work function metal layer 64, and a low resistance metal layer 66 are formed in the recess, and a planarizing process such as CMP is conducted to remove part of low resistance metal layer 66, part of work function metal layer 64, and part of high-k dielectric layer 62 to form metal gate. In this embodiment, the gate structure 24 or metal gate 54 fabricated through high-k last process of a gate last process preferably includes an interfacial layer or gate dielectric layer 30, a U-shaped high-k dielectric layer 62, a U-shaped work function metal layer 64, and a low resistance metal layer 66 as the high-k dielectric layer 62, the work function metal layer 64, and the low resistance metal layer 66 together serving as a gate electrode for each transistor or each device.

In this embodiment, the high-k dielectric layer 62 is preferably selected from dielectric materials having dielectric constant (k value) larger than 4. For instance, the high-k dielectric layer 50 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer 64 is formed for tuning the work function of the metal gate in accordance with the conductivity of the device. For an NMOS transistor, the work function metal layer 64 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 64 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 64 and the low resistance metal layer 66, in which the material of the barrier layer may include titanium (Ti), titanium nitride (TiN), tantalum (Ta) or tantalum nitride (TaN). Furthermore, the material of the low-resistance metal layer 66 may include copper (Cu), aluminum (Al), titanium aluminum (TiAl), cobalt tungsten phosphide (CoWP) or any combination thereof.

Next, part of the high-k dielectric layer 62, part of the work function metal layer 64, and part of the low resistance metal layer 66 are removed to form a recess (not shown), and a hard mask 68 is then formed into the recess so that the top surfaces of the hard mask 68 and ILD layer 52 are coplanar. The hard mask 68 could be made of material including but not limited to for example SiO₂, SIN, SION, SiCN, or combination thereof.

Next, a contact plug formation process could be conducted by forming another dielectric layer 70 on the ILD layer 52, conducting a photo-etching process by using a patterned mask (not shown) as mask to remove part of the dielectric layer 70 and part of the hard mask 68 directly on top of the gate structure 24 and part of the ILD layer 52 and part of the CESL 50 adjacent to the gate structure 24 for forming contact holes (not shown) exposing top surface of the gate structure 24, the source/drain region 40 and body region 44. Next, conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact holes, and a planarizing process such as CMP is conducted to remove part of aforementioned barrier layer and low resistance metal layer for forming contact plugs 56 electrically connecting the gate structure 24, the source/drain region 40, and the body region 44. This completes the fabrication of a semiconductor device according to an embodiment of the present invention.

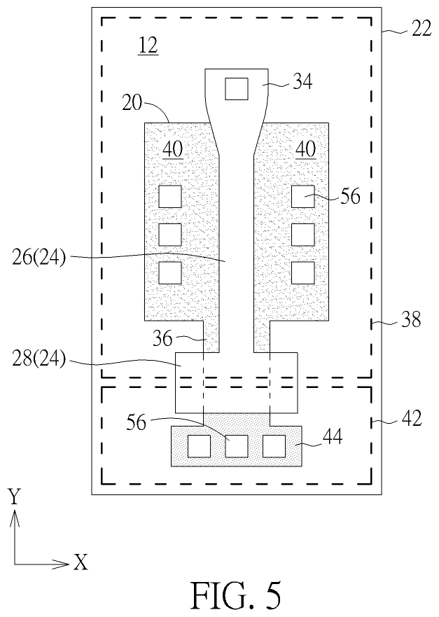

Referring to FIG. 5, FIG. 5 illustrates a top view of a RF device according to an embodiment of the present invention. As shown in FIG. 5, in contrast to the shielding structure 34 in FIG. 1 includes a rectangular extending along the X-direction and overlapping the source/drain region 40, the shielding structure 34 in this embodiment includes a funnel shape, in which the bottom surface of the funnel shaped shielding structure 34 extending along the X-direction is slightly less than the width of the horizontal portion 28 of the gate structure 24 also extending the X-direction and the portion of the funnel shape connecting the vertical portion 26 preferably overlaps part of the source/drain region 40. According to an embodiment of the present invention, the width of the bottom surface of the shielding structure 24 extending along the X-direction is less than 80%, 70%, 60%, or even 50% of the width of the horizontal portion 28 extending along the X-direction, which are all within the scope of the present invention.

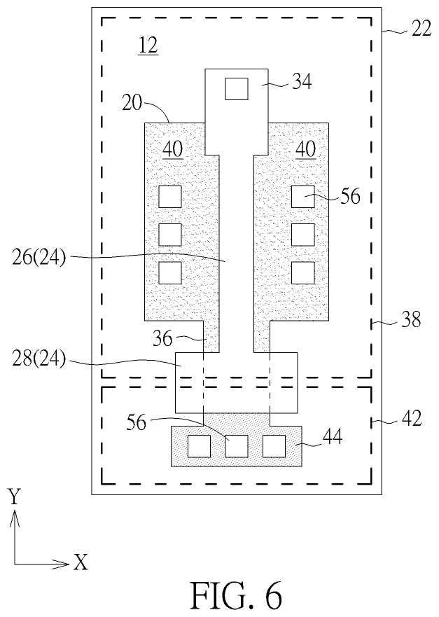

Referring to FIG. 6, FIG. 6 illustrates a top view of a RF device according to an embodiment of the present invention. As shown in FIG. 6, in contrast to the shielding structure 34 shown in FIG. 1 is extending along the X-direction and the width of the shielding structure 34 is substantially equal to the width of the horizontal portion 28, the rectangular shielding structure 34 in this embodiment is extending along the Y-direction for connecting to the vertical portion 26 of the gate structure 24, in which the width of the shielding structure 34 extending along the X-direction is less than the width of the horizontal portion 28 also extending along the X-direction. According to an embodiment of the present invention, the width of the shielding structure 34 extending along the X-direction is less than 80%, 70%, 60%, or even 50% of the extending width of the horizontal portion 28 along the X-direction, which are all within the scope of the present invention. It should be noted that even though the shielding structure 34 under the top view perspective pertains to be a rectangle in this embodiment, according to other embodiment of the present invention the shielding structure 34 could be a square shape having four equal sides, which is also within the scope of the present invention.

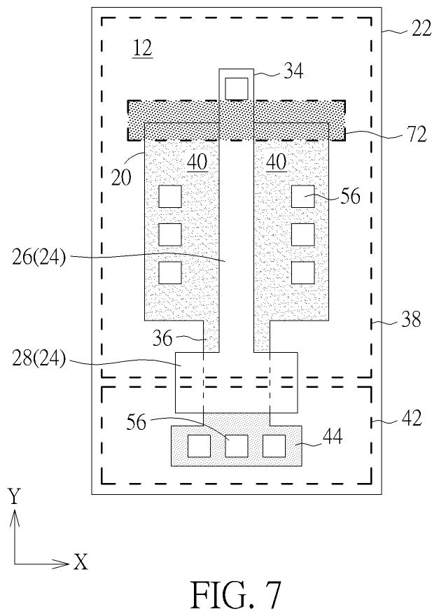

Referring to FIG. 7, FIG. 7 illustrates a top view of a RF device according to an embodiment of the present invention. As shown in FIG. 7, in contrast to all the aforementioned embodiments having a shielding structure 34 extending from the gate structure 24, the gate structure 24 of this embodiment only includes a vertical portion 26 and a horizontal portion 28 while not having any shielding structure extended from the gate structure 24. Moreover, the present embodiment preferably conducts an extra ion implantation process such as a tilted angle ion implantation process after forming the spacer and before forming the source/drain region 40 to form a doped region 72 extending along the X-direction on the substrate 12 adjacent to other another side of the gate structure 24. Preferably, the doped region 72 is extending across the vertical portion 26 of the gate structure 24 while overlapping the STI 22 and the edge of the source/drain region 40.

According to an embodiment of the present invention, the width of the doped region 72 extending along the X-direction is greater than the width of the source/drain region 40 extending along the X-direction as well as the width of the horizontal portion 28 of the gate structure 24 extending along the X-direction, in which the width of the doped region 72 extending along the X-direction could be greater than 10%, 20%, 30%, 40%, or even 50% of the width of the source/drain region 40 extending along the X-direction, or could be greater than 60%, 70%, 80%, 90%, or even 100% of the width of the horizontal portion 28, which are all within the scope of the present invention. It should also be noted that the doped region 72 and the source/drain region 40 preferably include different conductive type while the doped region 72 and the body region 44 both include same conductive type. For instance, the doped region 72 is preferably a p-type doped region and the concentration thereof is greater than the concentration of the body region 44.

Overall, the present invention provides a novel RF device structure which in the top view of FIG. 1 for instance extends a shielding structure 34 from an end of the T-shaped gate structure 24, in which the shielding structure 34 overlaps the edge of the STI 22 and part of the source/drain region 40 in the active area 20 such as the region above the neck doped region 36. Typically, issue such as inverse narrow width effect often results at the edge or corners of the STI due to thinning of the gate oxide layer or dopant segregation that eventually reduces breakdown voltage and increase current leakage. By using the aforementioned approach, it would be desirable to improve the inverse narrow width effect effectively and increase the performance of the device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A radio-frequency (RF) device, comprising:
a gate structure extending along a first direction on a substrate;
a source/drain region adjacent to two sides of the gate structure;
a shallow trench isolation (STI) around the source/drain region; and
a shielding structure extending from the gate structure and overlapping an edge of the STI.

2. The RF device of claim 1, wherein the gate structure comprises a T-shape.

3. The RF device of claim 2, wherein the T-shape comprises:
a vertical portion extending along the first direction; and
a horizontal portion extending along a second direction.

4. The RF device of claim 3, further comprising a body region adjacent to the horizontal portion.

5. The RF device of claim 4, wherein the body region and the source/drain region comprise different conductive type.

6. The RF device of claim 3, wherein the shielding structure is extending along the second direction.

7. The RF device of claim 3, wherein a width of the shielding structure is equal to a width of the horizontal portion.

8. The RF device of claim 3, wherein a width of the shielding structure is less than a width of the horizontal portion.

9. The RF device of claim 1, wherein the shielding structure comprises a funnel shape.

10. A radio-frequency (RF) device, comprising:
a gate structure extending along a first direction on a substrate;
a source/drain region adjacent to two sides of the gate structure;
a shallow trench isolation (STI) around the source/drain region; and
a doped region extending across the gate structure and overlapping an edge of the STI.

11. The RF device of claim 10, wherein the gate structure comprises a T-shape.

12. The RF device of claim 11, wherein the T-shape comprises:
a vertical portion extending along the first direction; and
a horizontal portion extending along a second direction.

13. The RF device of claim 12, further comprising a body region adjacent to the horizontal portion.

14. The RF device of claim 13, wherein the body region and the source/drain region comprise different conductive type.

15. The RF device of claim 12, wherein the doped region is extending along the second direction.

16. The RF device of claim 12, wherein a width of the doped region is greater than a width of the horizontal portion.

17. The RF device of claim 10, wherein the doped region and the source/drain region comprise different conductive type.
